(19) United States
(12) Patent Application Publication
(10) Pub. No.: US 2010/0253417 A1
(43) Pub. Date: Oct. 7, 2010

(54) Conducting Polymer for Electronic, Photonic and Electromechanical Systems

(75) Inventors: Douglas John Thomson, Winnipeg (CA); Michael Stephen Freund, Winnipeg (CA); Jun Hui Zhao, Winnipeg (CA); Rajesh Gopalakrishna Pillai, Winnipeg (CA)

Correspondence Address: FULBRIGHT & JAWORSKI L.L.P., 600 CONGRESS AVE., SUITE 2400, AUSTIN, TX, 78701, US

(73) Assignee: UNIVERSITY OF MANITOBA, Winnipeg, MB (CA)

(21) Appl. No.: 12/602,458

(22) PCT Filed: May 28, 2008
(86) PCT No.: PCT/IB2008/003470

§ 371 Date: May 14, 2010

Related U.S. Application Data
(60) Provisional application No. 60/940,478, filed on May 29, 2007.

(51) Int. Cl. G11C 5/14; H01L 51/30; H01L 51/00

(52) U.S. Cl. 327/530; 257/40; 257/E51.027; 327/493

(57) ABSTRACT

The present invention concerns doped organic semiconductors composites. In certain aspects, organic polymers are doped with large anions, such as DBS⁻ and small mobile cations. Electronic components comprising organic polymer circuits such as, memory circuits and arrays thereof are also provided.

### CROSS REFERENCE TO RELATED APPLICATION

This application claims priority to U.S. Provisional Patent Application Ser. No. 60/940,478, filed May 29, 2007, which is incorporated by reference.

### BACKGROUND

The invention concerns the field of semiconductors. More specifically, the invention concerns new conjugated organic semiconductors, composites and methods for their use.

### Description of Related Art

Since the original reports on the conductivity of polyacetylene (Chiang et al., 1977), there have been considerable efforts to develop semiconducting polymers for use in electronic devices (Angelopoulos, 2001). The primary focus has been on chemical modification in order to tune the band gap (Faied et al., 1995) as well as to control the carrier type (p and n-type) (MacInnes et al., 1981) and the carrier concentrations (Bredas & Street, 1985). Emphasis has been placed on developing materials that function in a manner that is analogous to inorganic semiconductors and on creating devices with traditional architectures such as transistors (Burroughes et al., 1988), p-n junctions (Cheng et al., 2004) and organic light emitting diodes (OLEDs) (Burroughs et al., 1990). At the same time, considerable focus has been placed on understanding and controlling the movement of counter ions into and out of semiconducting polymers in contact with electrolytes, and a wide range of devices have been developed based on redox switching such as batteries, supercapacitors and electrochromic devices (Gurunathan et al., 1999). Control over the identity of the ionic charge carrier can be imposed by immobilizing anions within the polymer either covalently (Patil et al., 1987) or by physical entrapment (Bidan et al., 1988), thereby forcing charge to be carried by smaller and more mobile cations.

In typical conjugated polymer systems, current conduction can be either electrode or bulk limited. For most conducting polymers, such as polypyrrole (PPy), with Au electrodes, the current is expected to be bulk limited (Blom et al., 1997). Several mechanisms of bulk conduction of charge can be dominant depending on geometry, field strength and carrier mobility among other things (Blom et al., 1997; Pai, 1970). At lower potentials between contact electrodes, ohmic behavior is expected. As the potential between the electrodes increases space charge limited currents (SCLC) often become dominate (Blom et al., 1997). With space charge limited current the injected charge carriers create a potential that limits the flow of charge (Blom et al., 1997). This results in a current which is nonlinear and increases as V² and 1/L³ in conventional semiconductors, in the absence of traps. However unlike conventional semiconductors, in conjugated polymers the mobility of the charge carriers increases with the applied field (Blom et al., 1997; Pai, 1970). This results in the current increasing more rapidly with voltage than would be predicted in the absence of field enhanced mobility (Blom et al., 1997; Pai, 1970). The modulation of field generated carriers by introducing ion pairs into a neutral conjugated polymer is described here.

### SUMMARY

In certain aspects, the present invention concerns organic semiconductors. In some aspects, organic compounds for use according to the invention may comprise conductive polymers or mixtures of conductive polymers such as polypyrrole (PPy), polyacetylene (PA), polythiophene (PT), polyaniline, polyphenylene (PPP), poly(phenylene vinylene) or derivatives thereof. Furthermore, in certain cases, organic polymers comprise doping with positively charged molecules (cation) and negatively charged molecules (anions). Preferably, doped polymers of the invention comprise a large immobile ion of one charge (i.e., a cation or anion) and a small mobile ion of a reverse charge. For example, a doped polymer may comprise at least a first small, mobile cation and at least a first large, less mobile anion. Thus, in certain aspects, an organic polymer may comprise doping with at least a first polyelectrolyte. Thus, ions comprised in a doped polymer of the invention may be mobilized upon the application of an electric potential. For example, a polymer of the invention may exhibit a change in current (upon potential application) equal to an effective change in effective length of between about 5 and 20%.

As discussed supra, in certain aspects, an organic polymer of the invention comprises doping with a large anion or a polyelectrolyte comprising a large anion or a mixture of large anions. In further aspects, an anion for use in the invention may have a molecular weight (MW) of between about 100 and 1,000,000. Furthermore, in some instances, an anion may be further defined as surfactant. In some cases, an anion for use in the invention may be monovalent, however it is also contemplated that divalent, trivalent or multivalent anions may be used. For example, in some very specific cases, an anion may be a polyacrylamidoglycolic acid (PAGA), poly(diallyldimethylammonium chloride) (PDMA), poly(sodium styrenesulfonate) (PSS), polystyrene sulfonate (SPS), poly(acrylic acid) (PAA), poly(vinyl phosphate) (PVP), poly(2-acrylamido-2-methyl-1-propanesulfonicacid) (PAMPS), poly(2-acrylamidoglycolic acid), poly(2-hydroxy-4-N-methacrylamidobenzoic acid) (PHMA), poly(sodium thiophene-3-carboxylate) (PSTC), poly(sodium phenylenecarboxylate) (PSPC), a sulfonated poly(benzobisthiazole) (PBT), sulfated poly((3-hydroxyether), sulfated poly(butadiene), sulfated poly(imide), sulfated poly(methacrylate), bis(2-ethylhexyl)sulfosuccinate, dodecylbenzenesulfonic acid (DBSA), dodecylbenzenesulfonate (DBS), dodecylsulfate, tetradecyltrimethylammonium bromide (TTAB), tetraethylammonium p-toluensulfonate, toluenesulfonate, pyrenesulfonate, pyrene-1,3,6,8-tetrasulfonate, dodecylbenzenesulfonate, 1,2-bis(decyloxycarbonyl)ethanesulfonate, octachloro-dirhenate (Re₂Cl₈) or tetraphenylborate anion or a combination thereof For instance, in some cases, an organic polymer may comprise doping with a dodecylbenzenesulfonate⁻ (DBS) anion or a polyelectrolyte such as sodium dodecylbenzenesulfonate. Furthermore, in some instances, a doped organic polymer of the invention may be defined by the concentration of an anion comprised in the polymer. Thus, in some cases, a doped polymer may comprise a ratio of polymer to anion of about 6:1, about 5:1 or about 4:1. In even more specific aspects the concentration of an anion in a polymer may be defined. For example, a doped polymer of the invention may comprise about 1×10²¹ anion molecules per cm³ as exemplified herein.

In still further aspects, it will be understood that doped polymers of the invention may comprise a small, mobile cation or a mixture of small mobile cations. For example, in certain cases, polymers may comprise doping with a second polyelectrolyte comprising a mobile cation. Furthermore, in some aspects, this doping process may proceed under reducing conditions. In preferred aspects, cations for use in the invention are small mobile cations having molecular weight of less than about 100, such as single atom ions. For instance, cations may be an alkali metal such as lithium. Thus, in certain cases, a polymer of the invention may be doped with a polyelectrolyte such as lithium perchlorate.

In yet further embodiments, polymers of the invention may comprise additional polymer layers or other ion containing layers. In some cases, such additional layers may be used to provide a barrier to lock in field produced I-V asymmetry. In still other aspects, polymer layers may be altered to modify ion mobility. For instance, polymers maybe driven through the glass transition temperature, or plasticizers may be added or removed to alter the glass transition temperature.

In still further embodiments, the invention provides a method comprising applying a first potential across an organic polymer of the invention, and applying a second potential across said polymer to generate a current that is dependent on the first potential that was applied across the organic polymer. In certain aspects, the second potential may be a reverse polarity with respect to the first potential. Preferably, the magnitude of the first and second potentials will be different. For example, in some cases, the difference in the magnitude of the first potential and the second potential is between about 3 and about 4.5 V. In still further aspects, the first potential may be greater than the magnitude of the second potential or visa versa. In some cases, the current generated by the second potential may be assessed, which may comprise measuring the current generated by second potential. Thus, in some aspects, assessing the current generated by said second potential may comprise determining whether the current generated by the second potential increases or decreases over time. In certain further aspects the distance of polymer over which a potential is applied may be defined. For example, a potential may be applied over a distance of polymer of between about 0.1 and about 100 μm, or between about 1 and about 20 μm, or between about 100 nm and about 500 nm, or about 200 nm.

Thus, in certain aspects, there is provided a method for determining whether a first potential has been applied across a doped organic polymer of the invention comprising (i) applying a potential across the polymer and (ii) applying (e.g., assessing) the current resulting from said potential thereby determining whether a potential has been previously applied across the polymer. Such a method therefore may used in the storage of binary data (e.g., 0 is no previous potential has been applied, 1 if a previous potential has been applied).

As exemplified herein, doped organic polymers of the invention may in certain cases, be used in electronic circuits. For example, in some aspects, the invention provides a circuit comprising an organic polymer doped with at least a first polyelectrolyte wherein said organic polymer is in electronic communication with at least a first and second conductor. Hence, organic polymers of the invention may fill a gap between two conductor materials. In certain cases, a circuit of the invention may be defined by the length of the gap filled by a doped polymer. For example, a doped polymer of the invention may fill a gap of between about 0.001 and 100 μm, or between about 0.1 and 100 μm, or between about 1 and 20 μm. In certain aspects the first or second conductor may be further defined as an injecting or blocking electrode. Furthermore, in certain cases the first or second conductor (or both) may comprise Au, Pt, Cu, Ag or an alloy or mixture thereof. In some preferred aspects, a circuit of the invention may be comprised in a non reactive environment such as a vacuum or an inert gas such as nitrogen or a noble gas. In some specific aspects a circuit of the invention maybe further defined as a memory circuit as exemplified herein.

Furthermore, in certain aspects, doped polymers of the invention may comprise additional polymer layer. For example, and additional polymer layer may be used to block the motion of ions that can be triggered by electric fields, magnetic fields, heat or light. Thus, such additional layer may reduce interference from undesired external sources.

In yet further aspects, the invention concerns an array comprising two or more circuits. Such an array for example may be comprised within an electronic device. For example, the invention provided in some aspects, a computer comprising a circuit or an array of circuits of the invention. In other embodiments, the array may be a sensor array.

Some embodiments of the present disclosure involve crossbar devices having a first conductor adjacent to a crossbar junction region, a second conductor adjacent to the crossbar junction region, and a doped organic polymer (e.g., as described above) that is within the crossbar junction region and is in electronic communication with the first conductor and the second conductor. In these embodiments, the first conductor and the second conductor may each have widths of less than about 100 μm and may be separated from each other by about 1 μm or less. In some embodiments, the first conductor and the second conductor may be separated from each other by as little as about 1 nm or less. Other dimensions can be used, as would be understood by those having ordinary skill in the art, with the benefit of this disclosure.

These crossbar devices can be configured such that a first potential can be applied across the organic polymer using the first conductor and the second conductor, and a second potential can be applied across the organic polymer using the first conductor and the second conductor to generate a current that passes through a portion of the first conductor, a portion of the organic polymer, and a portion of the second conductor. In these embodiments, the current that passes through the organic polymer (and therefore the crossbar junction region) when the second potential is applied is dependent on the first potential.

In some of these embodiments, the first conductor and the second conductor may be separated by between about 1 nm and about 500 nm. In some of these embodiments, this separation distance may be about 200 nm. In other embodiments, other dimension can be used, as would be understood by those having ordinary skill in the art, with the benefit of this disclosure.

In some embodiments of the present disclosure, the width of the first conductor and the width of the second conductor may be each about 20 μm or less. In some embodiments, the first conductor or the second conductor (or both) may be Au, Pt, Cu, Ag, tungsten oxide, or other metal oxides. Other materials can be used, as would be understood by those having ordinary skill in the art, with the benefit of this disclosure. In some embodiments, the materials contained in the first conductor and the materials contained in the second conductor may be identical. In some embodiments, the materials contained in the first conductor and the materials contained in the second conductor may be different.

Some embodiments of the present the disclosure involve memory devices. For example, two or more crossbar devices may form an array. In some embodiments, the array is a sensor array. In other embodiments, a computer contains the crossbar devices or arrays containing the crossbar devices. One of ordinary skill in the art, with the benefit of this disclosure, would understand that embodiments of the present disclosure may involve memory devices such as, for example, RAM, SRAM, DRAM, etc., that may be used in applications such as, for example, computers, cell phones, PDA devices, cameras, mobile electronics, etc.

Embodiments discussed in the context of a methods and/or composition of the invention may be employed with respect to any other method or composition described herein. Thus, an embodiment pertaining to one method or composition may be applied to other methods and compositions of the invention as well.

As used herein the specification, “a” or “an” may mean one or more. As used herein in the claim(s), when used in conjunction with the word “comprising”, the words “a” or “an” may mean one or more than one.

The use of the term “or” in the claims is used to mean “and/or” unless explicitly indicated to refer to alternatives only or the alternatives are mutually exclusive, although the disclosure supports a definition that refers to only alternatives and “and/or.” As used herein “another” may mean at least a second or more.

Throughout this application, the term “about” is used to indicate that a value includes the inherent variation of error for the device, the method being employed to determine the value, or the variation that exists among the study subjects.

The terms “comprise” (and any form of comprise, such as “comprises” and “comprising”), “have” (and any form of have, such as “has” and “having”), “include” (and any form of include, such as “includes” and “including”) and “contain” (and any form of contain, such as “contains” and “containing”) are open-ended linking verbs. Thus, a method comprising certain steps is a method that includes at least the recited steps, but is not limited to only possessing the recited steps.

Other objects, features and advantages of the present invention will become apparent from the following detailed description. It should be understood, however, that the detailed description and the specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The following drawing is part of the present specification and is included to further demonstrate certain aspects of the present invention. The invention may be better understood by reference to the drawing in combination with the detailed description of specific embodiments presented herein.

FIG. 1A-C: Scanning electron micrograph of an embodiment of a composite polymer device and schematic representation of band structure. FIG. 1A, SEM of the cross-section of an interdigitated electrode array showing two gold electrodes covered by a ˜5 μm thick PPy⁰Li⁺DBS⁻ film. FIG. 1B-D, schematic electron energy level diagram for a reduced PPy polymer containing immobile anions compensated by mobile cations. As grown, the polymer contains sufficient immobilized anions to compensate holes that would be present in its fully oxidized state; however in the reduced state shown, mobile cations are present to maintain charge neutrality. FIG. 1B, upon application of a potential, initially, the field equilibriates across the gap between electrodes separated by distance L and a space charge limited current or resistive current flows between the electrodes. FIG. 1C, in response to the field, cations drift resulting in the formation of a double layer, allowing hole injection and the formation of an anion stabilized region with lower resistance, thereby reducing the effective L through which space charge limited current or resistive current flows. FIG. 1D, reversal of the polarity results in field driven movement of cations dispersing the double layer and reformation at the opposite electrode. When the potential step is asymmetric, the evolution of L with time will be a function of the previous potential applied and thus contains a “memory effect”.

FIG. 2: X-ray photoelectron spectra (XPS) of polypyrrole NaDBS composite on gold. In this particular case, Na⁺ was used instead of Li⁺ due to the higher sensitivity of XPS for Na relative to Li.

FIG. 3A-B: PPy⁰Li⁺DBS⁻ device current-voltage behavior. FIG. 3A, I-V behavior (scan rate of 0.01 V/s) of a polypyrrole composite device in the oxidized state as grown prior to reduction (PPy⁺DBS⁻, indicated by the solid line) and in the reduced state with Li⁺ incorporated (PPy⁺DBS⁻Li⁺) into the film. A reduced polypyrrole film deposited in the same way but with no surfactant present is shown) (PPy⁰) for reference. Shaded areas indicate ohmic behavior, space charge limited current (SCLC) behavior and eventually SCLC with field generated carrier current (FGCC) region. FIG. 3B, Current as a function of time following the application of voltages spanning the SCLC and FGCC regions and normalized to the initial current. At lower voltages where SCLC is a major component of the total current and ion drift is not significant, steady-state current is achieved rapidly; however at larger voltages, ion drift resulting in FGCC is observed requiring significantly more time to approach steady state.

FIG. 4A-B: The current versus time behavior of an embodiment of a polypyrrole composite device. The device's behavior can be explained by field generation of a conducting region. An applied potential causes a redistribution of cations resulting in a junction with a reduced effective length and increased current. The junction remains in this state for a period of time after the field is removed, as the cations do not instantaneously return to their equilibrium position. Upon reversing the applied potential, it is hypothesized that the internal configuration of charge and carriers remains largely unchanged. If the magnitude of the reversed potential (⁻2 V for the inset traces) is smaller than the previous forward potential the current will decrease with time as the cations drift to increase effective junction width. The cations return to the equilibrium configuration much more slowly in the absence of an applied field. When a delay time (T₀) is introduced between the forward and reverse potential the effects of the cation redistribution can be observed for time periods exceeding 80 seconds (FIG. 4B). This behavior constitutes a memory and is analogous to an “echo” related to the potential applied prior to the potential reversal. This echo effect increases with increasing initial potentials (FIG. 4A).

FIG. 5A-B: A dynamic memory device embodiment based on polypyrrole composite. FIG. 5A, the schematic of a memory circuit, designed to capture two distinct current transit behaviors corresponding to the cation distribution in the device. Clock 1 controls whether a read voltage or a write voltage is applied to the device. In the write state VW=0 is applied for the low state and VW=2V is applied for the high state. In the read state V=−1.5V is applied and the current sensed through the resistor. This signal is amplified and the sample and hold amplifier 1 captures the signal shortly after the application of the read voltage. Sample and hold amplifier 2 captures the signal several seconds later. Clock 4 loads the memory state into a flip/flop several seconds after sample and hold 2 is triggered. This storage mechanism is interesting in that the information is extracted from a self referenced signal. FIG. 5B, The wave forms for the read-write clock (CLK), the current passing through the polypyrrole composite, and the output of the memory cell during the storing and reading back the bit sequence 10011011.

FIG. 6: Stability of current-voltage behavior in an embodiment. Current-voltage characteristics of a device under nitrogen at a scan rate of 10 mV/s demonstrating reversibility and stability.

FIG. 7A-B: Fabrication of smaller polypyrrole composite device embodiment. Optical micrograph of gold electrodes with an approximately 1 μm gap before (FIG. 7A) and after (FIG. 7B) deposition of a PPy composite.

FIG. 8A-B: Current-voltage behavior for the device in FIG. 7. FIG. 8A, the I-V behavior (scan rate of 0.01 V/s) of the polypyrrole composite device in the reduced state with Li⁺ incorporated into the film exhibits nonlinear behavior similar to that exhibited in FIG. 3. FIG. 8B, current as a function of time following the application of voltages spanning the SCLC and FGCC regions and normalized to the initial current as in FIG. 3. At lower voltages steady-state current is achieved rapidly; however at larger voltages, ion drift resulting in FGCC is observed requiring significantly more time to approach steady state, although significantly less time in comparison to the device in FIG. 3 with larger electrode spacing.

FIG. 9A-B: Current versus time behavior of the polypyrrole composite device in FIG. 7. FIG. 9A, the device's behavior is similar to that observed for the device containing larger electrode spacing (FIG. 4) with the exception of the time scale of the behavior related to ion drift. FIG. 9B, as expected, for the smaller spacing, these time scales are approximately an order of magnitude shorter. When a delay time (T₀) is introduced between the forward and reverse potential the effects of the cation redistribution can be observed for time periods less than 8 seconds.

FIGS. 10A-10B: Embodiments of crossbar devices. The first conductor, second conductor, organic polymer within the crossbar junction region, and generated current are depicted.

FIG. 11: Current-voltage characteristics of an embodiment of the crossbar device of FIG. 10. Ohmic, SCLC, and FGCC regions are shown.

FIG. 12: Current as a function of time of an embodiment of the crossbar device of FIG. 10.

FIG. 13: The time dependent conductance related to the field driven ions redistribution is shown for an embodiment of the crossbar device of FIG. 10.

FIG. 14: Current as a function of time for an embodiment of the crossbar device of FIG. 10 showing two transient conducting states that can be produced by manipulating the applied field.

FIG. 15: A schematic of an embodiment of a memory circuit that contains the crossbar device of FIG. 10.

FIG. 16: The waveforms of the memory circuit of FIG. 15 captured with the read-write clock (CLK), the current signal passing through the polymer junction, and the output of the memory cell corresponding to the writing and reading back the bit sequence 11100011100

### DESCRIPTION OF ILLUSTRATIVE EMBODIMENTS

Herein there is provided examples demonstrating conjugated semiconducting polymer composite comprising immobile anions that act as a counter ion for the oxidized (more conductive) form of the polymer and highly mobile cations that can balance the charge of the immobile anions in the presence of the reduced (less conductive) form of the polymer. This material exhibits a field-dependent resistance in the solid state with a time dependence that is a function of the mobility of the cation. Using this approach, a functioning dynamic memory device has been demonstrated. These findings should open-up new directions for the development of organic-based electronics that utilize field- and time-dependent behavior of organic semiconducting composites.

The material system described in this work has significant advantages for application in nanometer-scale electronics, since the junctions are electrochemically grown and they can be fabricated after all conductor layers have been deposited and patterned. For example, in a cross-bar memory architecture, these junctions can be grown after the formation of the crossbars rather than between the metal layers (Green et al., 2007). The bulk dominated conductance of this system should result in better scaling with device size. If the dimensions of the device were all scaled by a factor of 1/s then the space charge limited current would scale as s³ with the device length and 1/s² with device area resulting in an overall scaling of s³/s²=s. In interface-dominated devices, such as diodes, the current would scale as s⁻² resulting in currents for nanometer-scale devices being very small (Cerofolini & Mascolo, 2006).

In summary, the invention provides a new approach for the design of conjugated conducting polymer composites that exhibit dynamic asymmetric electronic behavior based on the movement of charge in response to the application of a field. This work opens up new avenues for device design and fabrication. Devices utilizing this material offer several potential advantages including ease of fabrication, simple structures and more favorable scalability factors.

### Examples

The following examples are included to further illustrate various aspects of the invention. It should be appreciated by those of skill in the art that the techniques disclosed in the examples that follow represent techniques and/or compositions discovered by the inventor to function well in the practice of the invention, and thus can be considered to constitute preferred modes for its practice. However, those of skill in the art should, in light of the present disclosure, appreciate that many changes can be made in the specific embodiments which are disclosed and still obtain a like or similar result without departing from the spirit and scope of the invention.

### Example 1

### Preparation of IDA/Polymer Structures

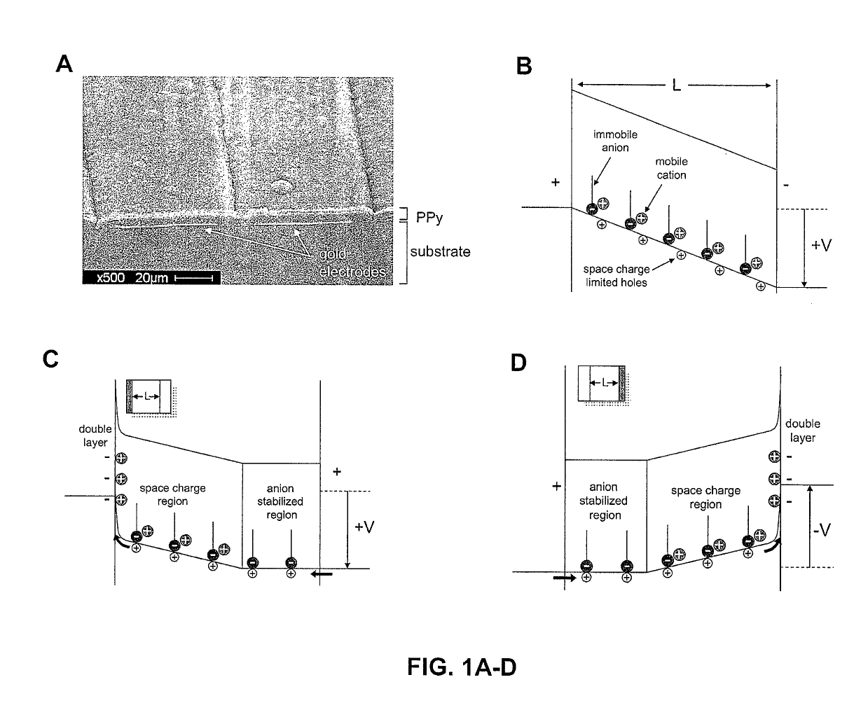

In order to produce IDA/polymer structures, a PPy composite material containing immobilized dodecylbenzenesulfonate (DBS) and lithium (Li⁺) in the form of a thin film spanning two metal electrodes was created (FIG. 1A) in an interdigitated electrode array (IDA) configuration. By performing the electrochemical polymerization of pyrrole in the presence of NaDBS as electrolyte, DBS⁻ is incorporated into the polymer (˜10²¹/cm³) at a level capable of stabilizing the oxidized (conducting form) of the polymer. Subsequent reduction of the polymer, in the presence of lithium perchlorate as electrolyte, results in the generation of Li⁺DBS⁻ in the neutral (nonconducting form) of the polymer. The gold interdigitated array electrodes (IDAs) used for these studies were obtained from Biomedical Microsensors Laboratory at North Carolina State University. Each of these arrays contains 2.8 mm×0.075 mm gold electrodes with a gap width of 20 μm having a total exposed area of 6.09 mm². The polypyrrole (PPy) films were grown across the IDA electrodes using an aqueous solution of freshly distilled pyrrole monomer (100 mM) and an electrolyte (100 mM, NaDBS or LiClO₄) at a constant potential of +0.65 V vs. Ag/AgCl. The thickness of the polypyrrole films were controlled by passing specific amount of charge (200 mC/cm² for 1 μm thick film) during the electrodeposition (Smela, 1999). In each case, 1.23 C/cm² of charge was passed to achieve complete bridging of the IDA electrodes and resulted in a film thickness close to 6 μm as seen in FIG. 1A.

Preparation Methods

The gold interdigitated array electrodes (IDAs) were obtained from

Biomedical Microsensors Laboratory at North Carolina State University. Each of these arrays contains 2.8 mm×0.075 mm gold electrodes with a gap width of 20 μm having a total exposed area of 6.09 mm². The polypyrrole (PPy) films were grown across the IDA electrodes using an aqueous solution of freshly distilled pyrrole monomer (100 mM) and an electrolyte (100 mM, NaDBS or LiClO₄) at a constant potential of ⁺0.65 V vs. Ag/AgCl. The thickness of the polypyrrole films were controlled by passing specific amount of charge (200 mC/cm² for 1 μm thick film) (Smela, 1999) during the electrodeposition. In each case, 1.23 C/cm² of charge was passed to achieve complete bridging of the IDA electrodes and resulted in a film thickness close to 6 μm as seen in FIG. 1A. All electrochemical experiments were performed using a CHI660 electrochemical workstation (CH Instruments) and solutions were purged with nitrogen for at least 15 minutes prior to electrochemical measurements.

### Scanning Electron Microscopy (SEM) Analysis

Samples were prepared by mechanical cutting and shaving of the PPy-IDA cross-sectional interface using a razor blade. The finely cut samples were sputter-coated (Edward) with a thin layer of gold and the images were acquired with a Cambridge Stereoscan 120 Scanning Electron Microscope.

### X-Ray Photoelectron Spectra Analysis

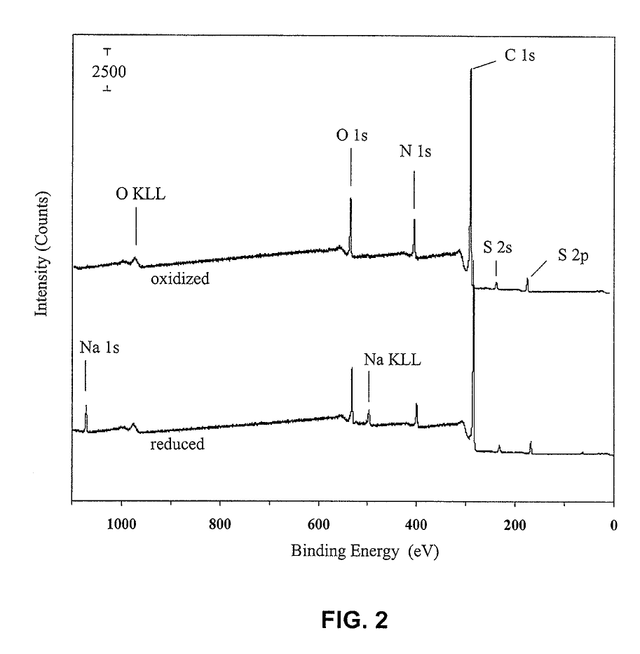

The X-ray photoelectron spectra of polypyrrole NaDBS composite on gold was determined (FIG. 2). During the electrochemical polymerization of pyrrole in the presence of NaDBS as electrolyte, the deposited polymer is oxidized. The ratio of nitrogen (in the pyrrole unit) to sulphur (in DBS⁻) is approximately 5-to-1 as expected for the case where polypyrrole is oxidized and DBS− is present as a counter ion. Upon reduction of the polypyrrole in the presence of electrolyte, the cation enters the polymer to balance the charge of the DBS−, which is immobile in the polymer. In this particular case, Na⁺ was used instead of Li⁺ due to the higher sensitivity of XPS for Na relative to Li. The XPS results demonstrate that DBS− remains within the film at approximately the same level (N:S, 4:1) and that Na+ is incorporated at a level equal to that of DBS⁻ (Na:S, 1:1).

TABLE 1

| | |
|---|---|
| Integrated | Atomic |
| Peak Intensity* | ratios |

| | N 1s | S 2p | Na 1s | N:S | Na:S |
|---|---|---|---|---|---|
| Oxidized | 3022.8 | 542.9 | — | 5.5 | — |
| Reduced | 2540.0 | 627.8 | 635.1 | 4.0 | 1.0 |

*corrected with the relative sensitivity factors of the corresponding elements.

### Example 2

### Conductive Properties of IDA/Polymer Structures

The current-voltage (I-V) properties of the PPy-IDA devices were characterized under a nitrogen atmosphere with CHI660 electrochemical workstation (CH Instruments) or a Hewlett Packard 4145A semiconductor parameter analyzer. In the configuration described above (PPy⁰Li⁺DBS⁻, FIG. 1B), when a potential is applied across the material, Li⁺ can drift in the field, leaving behind DBS⁻, which can in turn stabilize the injection of holes and the formation of a region of higher conductivity (PPy⁺DBS⁻), resulting in a smaller effective L as illustrated in FIG. 1C.

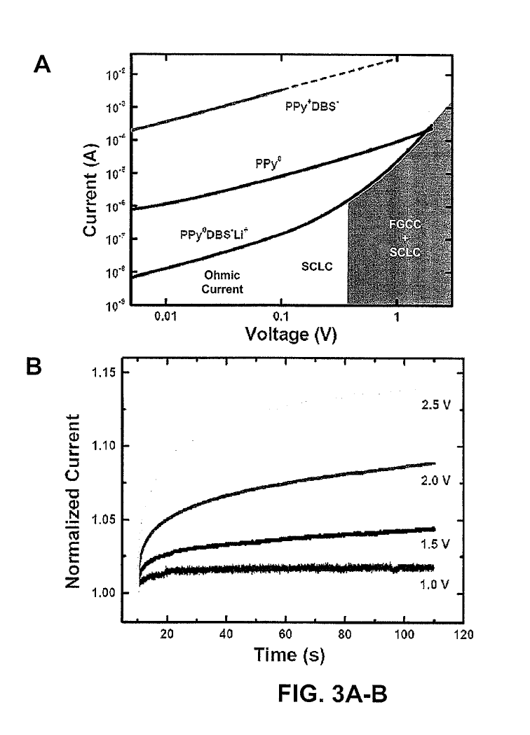

The bulk-limited current behavior of the PPy devices can be observed in current versus voltage curves (FIG. 3A). In the control device, where the polymer has been reduced without the presence of an immobilized anion)(PPy⁰), behavior is almost completely linear with little evidence for space charge limited current. In the composite device (PPy⁰Li⁺DBS⁻), at low voltages the current also increases linearly as expected, although characteristic of a higher resistance presumably associated with the presence of LiDBS (˜57% LiDBS by weight). However, when the voltage exceeds 0.2 V the current begins to increase super linearly and can be fit to a V² relationship with field dependant mobility, which is in agreement with other work on conjugated polymers (Blom et al., 1997; Pai, 1970). As the voltage increases past approximately 1 V the device enters a regime where it is no longer a static material, but begins to change the internal configuration of ionic species through drift (deMello et al., 1998) resulting in a region containing anion-stabilized charge carriers. This process is completely reversible in a nitrogen environment and under vacuum.

The time-dependant behavior of the current through these devices offers further evidence of this internal reconfiguration leading to a structure as shown in FIG. 1C. After the application of a potential, current begins to flow as shown in FIG. 3B. At potentials below that were drift becomes significant, the temporal behavior of the current (FIG. 3B) remains constant. At higher applied potentials this changes and the current increases with time before approaching a new equilibrium. This behavior is attributed to the drift of the cations resulting in a concomitant increase in anion stabilized conducting region shown in FIG. 1C and a decrease in the effective distance between electrodes and hence an increase in the current. Using a simple one-dimensional model the current changes observed in these junctions correspond to an effective change in length of about 5-20%.

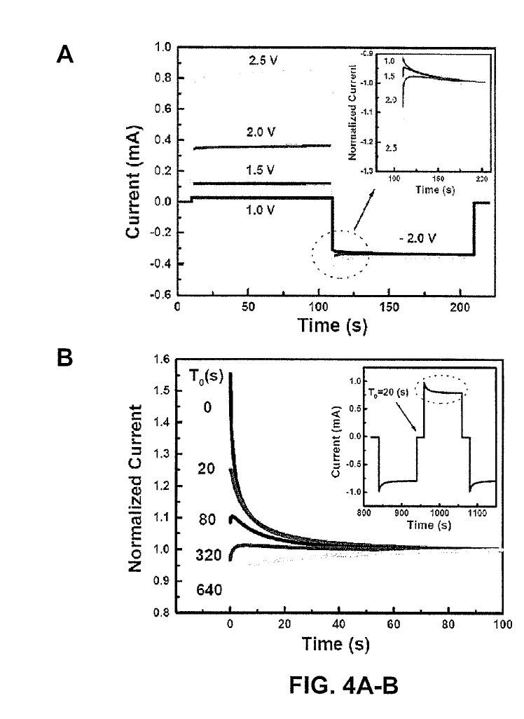

This redistribution of cations with voltage and time dependence offers new opportunities to produce electronic devices, such as dynamic memory cells and sensor arrays. For example, the redistribution of cations, that results in a junction with a reduced effective length, remains for a period of time after the field is removed since the cations do not instantaneously return to their equilibrium position. Indeed, one would expect that upon reversing the applied potential, the internal configuration of charge and carriers remains largely unchanged. A reverse potential can be used to determine the magnitude of the previously applied potential. If the magnitude of the reversed potential is greater than the previous forward potential, the magnitude of the current will increase with time as the cations drift and reduce the effective length of the junction. If the magnitude of the reversed potential is smaller than the previous forward potential, the current will decrease with time as the cations drift to increase the effective junction width. This memory effect is analogous to an “echo” related to the potential applied prior to the potential reversal. This echo effect increases with increasing initial potentials as is observed in FIG. 4.

Since the distribution of cations that results in the echo is detectable for periods over 60 s (FIG. 4B), this phenomenon can form the basis of a dynamic memory cell. In such a cell, the two states of the memory would be: 1) a junction to which a write voltage has been applied and 2) a junction to which no write voltage has been applied. The cell can be read with a voltage of magnitude lower than the voltage used to set the state. When a read voltage is applied to a junction where no write voltage was applied the current will start off low and rise to a higher steady-state current as the cations move (see FIG. 4A, inset). If a voltage is applied to a junction where a write voltage was applied, the current will start off higher and settle to a lower steady-state current as the cations reach a new equilibrium set by the read voltage (FIG. 4A, inset).

### Example 3

### Construction of a Simple Memory Circuit

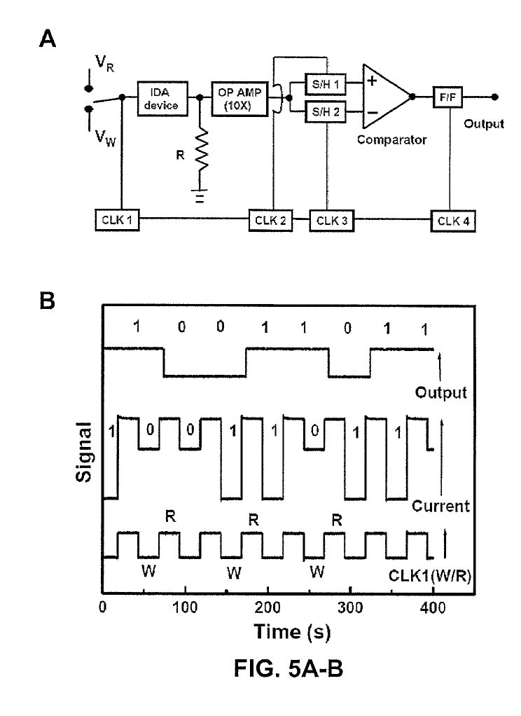

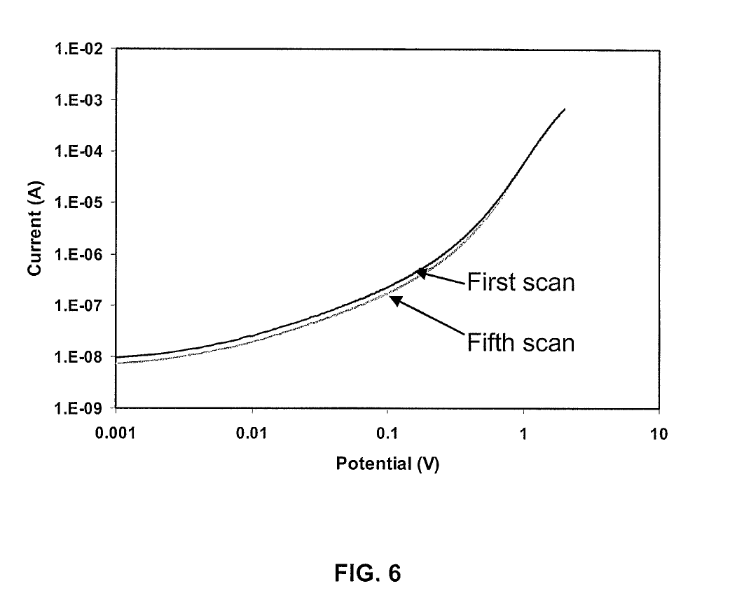

Using this principle, a simple memory circuit was constructed (FIG. 5A). The information is written into the cell using a write voltage as described above; the state of the cell is read out by comparing the current immediately after the application of the read voltage with the steady-state current (see FIG. 5A). If the current starts out higher than the steady-state value, a logic level high will be read out. If the current starts out lower, a logic level low will be read out (see FIG. 5B). The read function also acts to erase the state of the cell. No sequence of 1's and 0's were found that produced an error. This circuit is similar to conventional dynamic random access memory (DRAM) circuits where a reference capacitive line is charged and then differentially compared using an amplifier to a second capacitive line (Lu & Chao, 1984). As shown in FIG. 6, circuits described here can be scanned multiple times without significant signal degradation.

Testing Methods

The voltage applied to the PPy device in series with a resistor (R=50 Ω) was supplied with a DS345 Synthesized Function Generator, and its synchronous signal (CLK1) was used to trigger pulses (CLK2, CLK3 and CLK4) generated by the HP 8016A word generator. The current flowing through the device was read out from voltage across the resistor, which was then amplified 10 times by a differential amplifier (Op AMP AD621). Furthermore, two sample and hold amplifiers (LF398A) were used to record initial and stable states of the current, and their values were compared using comparator (LM311). At the final stage, a dual D-type flip/flop (SN74LS74A) was used to capture the memory data.

### Example 4

### Reduced Scaling of Circuits

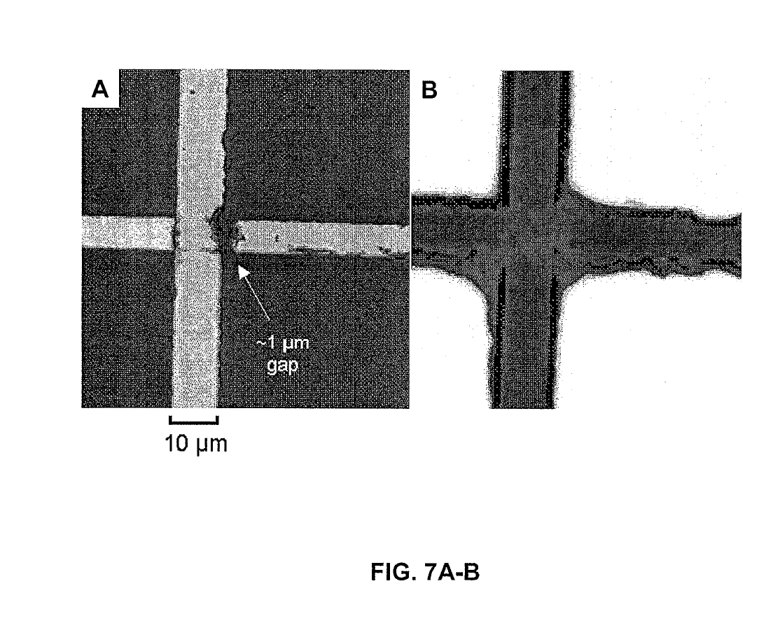

A smaller polypyrrole composite device was fabricated having a ˜1 μm gap as opposed to the larger gap in the device shown in FIG. 1. An optical micrograph of the gold electrodes of this smaller device is shown in FIG. 7, before (FIG. 7A) and after (FIG. 7B) deposition of a PPy composite.

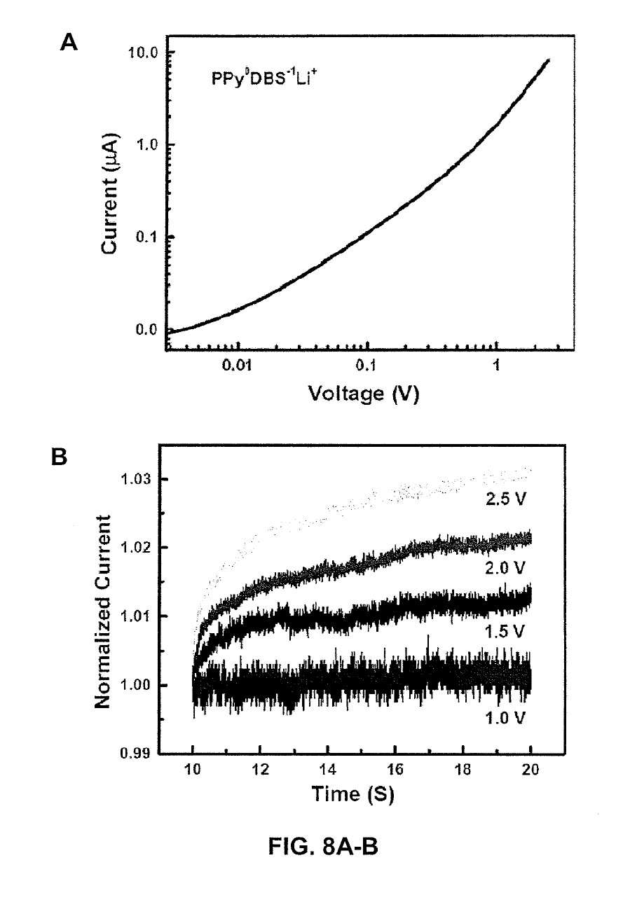

Current-voltage behavior for the device in FIG. 7 was analyzed and was found to be similar to that of the device of FIG. 1. The I-V behavior (scan rate of 0.01 V/s) of the polypyrrole composite device in the reduced state with Li⁺ incorporated into the film exhibits nonlinear behavior similar to that exhibited in FIG. 3 (See FIG. 8A). At lower voltages steady-state current is achieved rapidly while at larger voltages, ion drift resulting in FGCC is observed requiring significantly more time to approach steady state (FIG. 8B). Significantly less time is required in comparison to the device in FIG. 3 with larger electrode spacing.

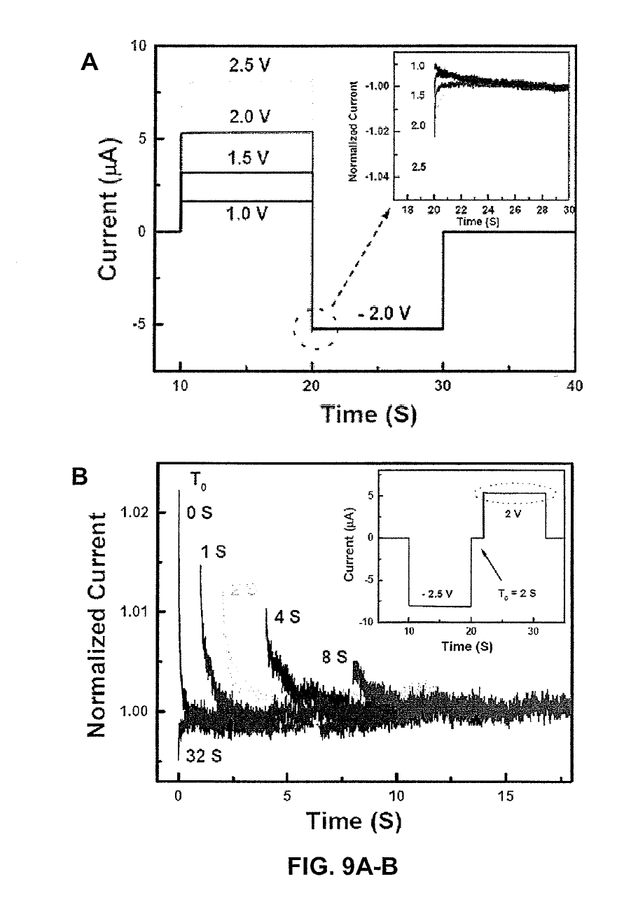

Current versus time behavior of polypyrrole composite device in FIG. 7 was also studied. The device's behavior is similar to that observed for the device containing larger electrode spacing (FIG. 4) with the exception of the time scale of the behavior related to ion drift (FIG. 9A). As expected, for the smaller spacing, these time scales are approximately an order of magnitude shorter. When a delay time (T₀) is introduced between the forward and reverse potential the effects of the cation redistribution can be observed for time periods less than 8 seconds. The time scale of this “memory” remains significantly longer than required for standard DRAM applications where refresh rates are typically on the order of 100 ms. These results suggest that there is room for at least another order of magnitude reduction in size. It is reasonable to expect even further reduction in size by pursing strategies for decreasing drift rates.

### Example 5

### Construction of a Crossbar Memory Device at a Submicron Level

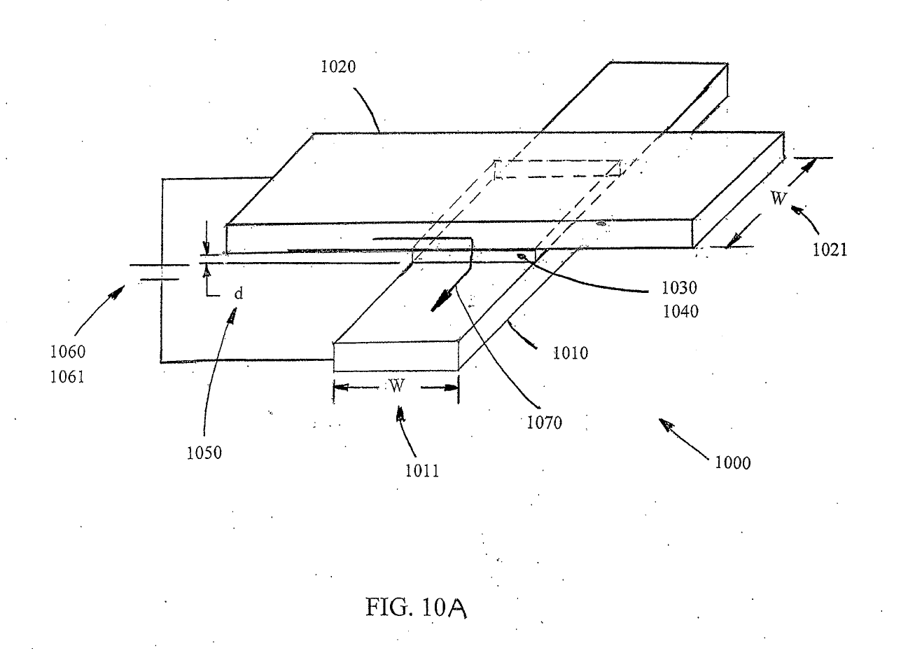

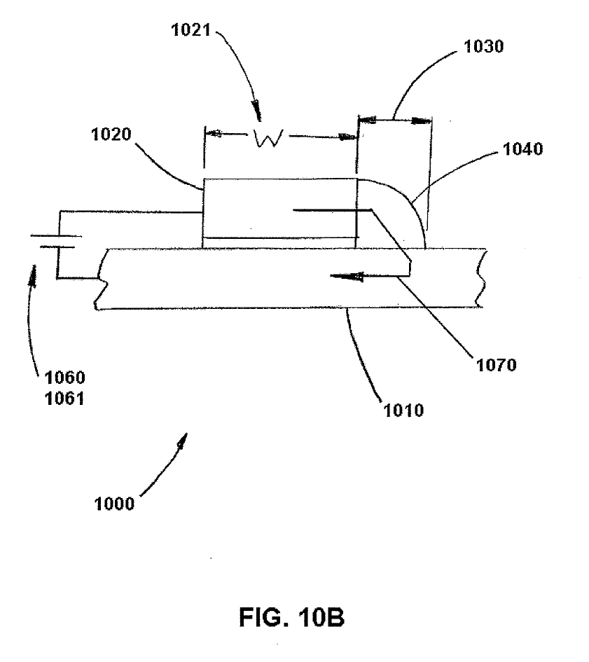

Referring to FIGS. 10A and 10B, embodiments of a polymer based crossbar junction (crossbar device 1000) are depicted. In these embodiments, crossbar devices may be fabricated by initially constructing two layers of perpendicularly crossed electrodes (first conductor 1010 having width 1011, and second conductor 1020 having width 1021). Gold electrodes were used in the exemplary embodiment discussed below, but one of ordinary skill in the art will recognize that many other suitable conductors may be used (e.g., tungsten oxide and other metal oxides, silver, platinum, copper), and that first conductor 1010 may be of a different materials than that contained in second conductor 1020. In these embodiments, first conductor 1010 and second conductor 1020 are not in contact, being separated by separation distance 1050.

FIG. 10A depicts an embodiment in which crossbar junction region 1030 is the region adjacent to both first conductor 1010 and second conductor 1020, with first conductor 1010 and second conductor 1020 being on opposite sides of crossbar junction region 1030.

In the embodiment depicted in FIG. 10B, crossbar junction region 1030 is adjacent to both first conductor 1010 and second conductor 1020, and first conductor 1010 and second conductor 1020 are not on opposite sides of crossbar junction region 1030. Instead, crossbar junction region 1030 spans a volume that is in contact with two surfaces of the respective conductors that are not parallel. Other embodiments may contain other spatial relationships between crossbar junction region 1030, first conductor 1010 and second conductor 1020 in which both first conductor 1010 and second conductor 1020 are adjacent to crossbar junction region 1030.

Organic polymer 1040 may be within crossbar junction region 1030 and in contact with both first conductor 1010 and second conductor 1020. Although FIG. 10B depicts organic polymer 1040 as contacting the entire height of the portion of second conductor 1020 near first conductor 1010, some embodiments of the present disclosure may include organic polymer 1040 that spans only a fraction of the height of the portion of second conductor 1020 near first conductor 1010.

An exemplary embodiment of the present crossbar junction was fabricated. In this embodiment, width 1011 of first conductor 1010 and width 1021 of second conductor 1020 were each 20 μm. Separation distance 1050 was 200 nm. To form organic polymer 1040, polypyrrole (PPy) thin films were electrochemically grown across crossbar junction region 1030 from the bottom of second conductor 1020 to the top of first conductor 1010 using an aqueous solution of freshly distilled pyrrole monomer (100 mM) and an electrolyte (100 mM, NaDBS) at a constant potential of +0.65 V vs. Ag/AgCl. A polymer in the form of PPy⁺DBS⁻ was synthesized in an oxidized state (e.g., a P-doped conducting state). The thickness of the thin films was controlled by passing specific amount of charge (200 mC/cm² for 1 μm thick film) during the electrochemical deposition. The oxidized film was then reduced in an electrolyte LiClO₄ through incorporating small Li cations into the polymer for balancing the charges of DBS anions, which changes the conductivity of the polymer into a semiconducting/insulting state. Thus, the polymer composite in the form of PPy⁰(DBS-Li+) in a charge neutral state was created. For PPy composite junctions in this embodiment, all electrochemical experiments were performed using a CHI660 electrochemical workstation (CH Instruments), and their electrical transport were characterized under a nitrogen atmosphere with CHI660 electrochemical workstation (CH Instruments) or a Hewlett Packard 4145A semiconductor parameter analyzer. Other embodiments may employ different materials in different dimensions.

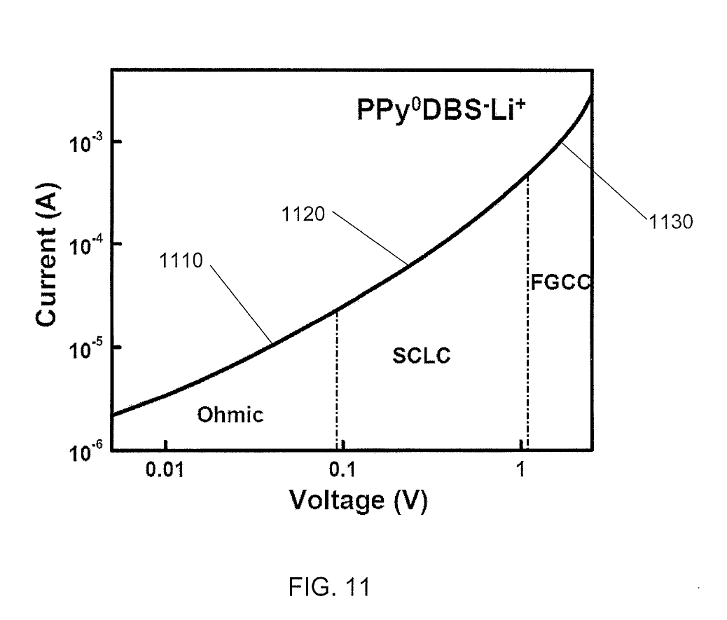

The current-voltage characteristics of crossbar device 1000 were investigated. Referring to FIG. 11, a linear relationship of current-voltage indicating ohmic conduction was seen at low voltage (ohmic region 1110). With an increase in first potential 1060 applied across crossbar junction region 1030, a nonlinear behavior in SCLC region 1120 suggests that the space charge limited current (SCLC) starts to become dominant, which is usually proportional to the V² and 1/L³ in the absence of trapping effect (where V is the applied voltage and L is the distance of the SCLC passing between second conductor 1020 and first conductor 1010).

Further increasing first potential 1060 drove the conductance state into a regime (FGCC region 1130) where the field generated charge carriers (FGCC) began to make a contribution to total current. The FGCC was produced because the drift of mobile Li+ ions (under the external field and the space charge induced field) left behind the immobile anions (DBS) stabilized region in a high conducting state. As a result, the configuration of internal ions species was changed and caused reduction of the effective conductance path L that the space charge limited current flowed through, thus giving rise to the FGCC current.

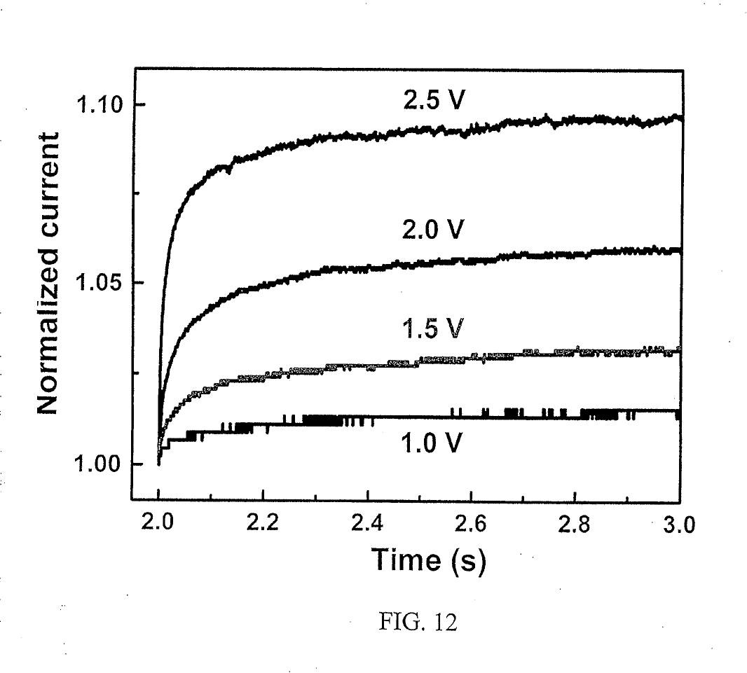

The FGCC current was evidenced by measuring the time dependence of current 1070 flowing through crossbar junction region 1030. Referring to FIG. 12, at higher applied potentials current 1070 increases with time before approaching a new equilibrium. This is associated with the reduced effective conductance distance L induced due to the drift of cations driven by the field.

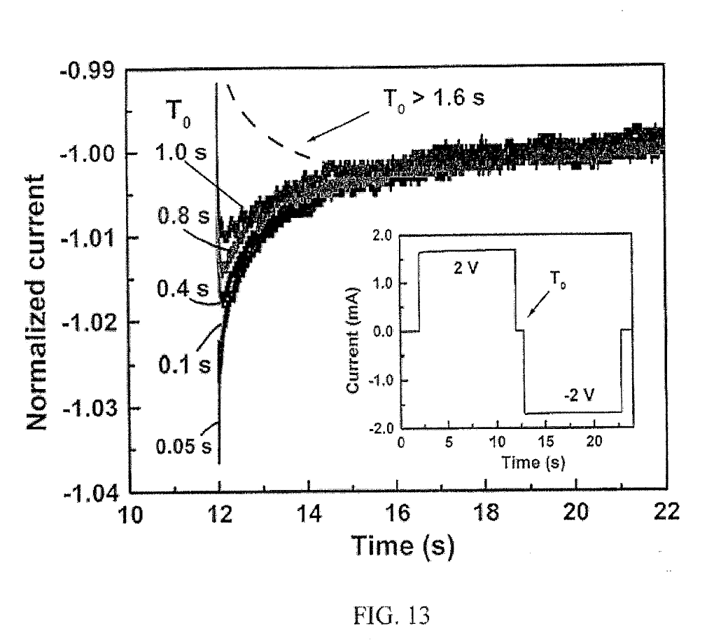

The time dependent conductance related to the field driven ions redistribution was also observed with further measurements as shown in FIG. 13. Here, a delay time (T0) was introduced between the forward and reverse field as shown in the inset. The effect of the ion redistribution was observed for time periods of about 1 second.

For cases where a very short field-free time was implemented before reversing the applied field, the cations could not return to their original equilibrium positions after the field was removed. Therefore, the internal configuration of charges and carriers that was established under the forward field did not change significantly. In contrast, for cases where the field-free time was more than 1 second, the ion distribution that was established under the forward field returned to its initial equilibrium state, and the current under the reversed field behaved the same as when the forward field was applied at the first time.

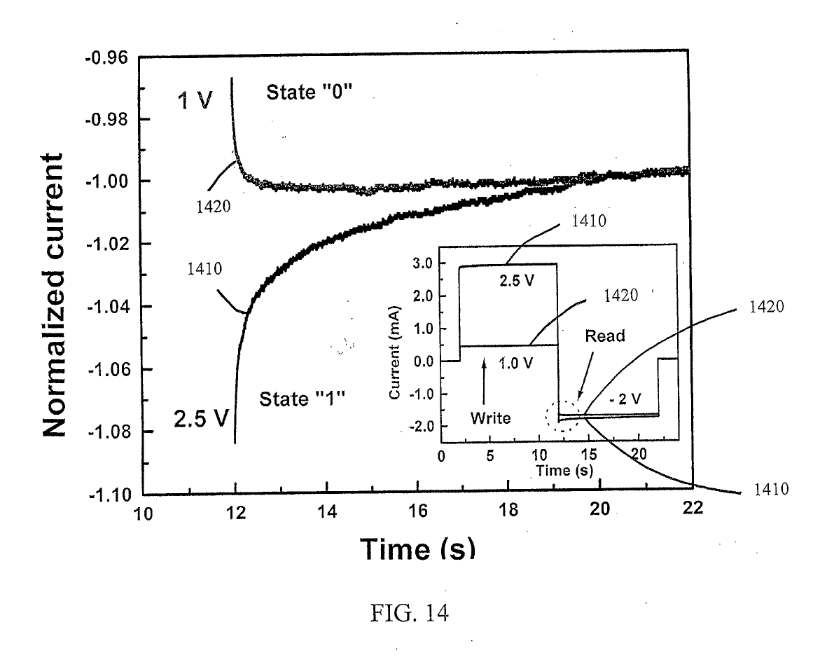

As experimentally observed above, the conductance state of crossbar junction region 1030 can be determined by the internal configuration of charges and carriers that are pre-established under the field. This can produce useful transient current behaviors that can be controlled by reversing the field relative to the previously applied field. Referring to FIG. 14, it was experimentally shown that when the magnitude of the reversed field is greater than that of the previous forward field, the magnitude of current 1070 will increase with time because the effective distance L of the junction becomes shorter. When the magnitude of the reversed field is smaller than the previous forward field, current 1070 will decrease with time as the drift of cations increases the effective junction width L. Therefore, two transient conducting states can be produced by manipulating the applied field as shown in the inset of FIG. 14. The two transient conductance states, representing the state “1” (response state high 1410) and the state “0” (response state low 1420) as shown in the main body of FIG. 14, can be employed to construct a dynamic memory cell. Referring to FIG. 10, in such a cell state high “1” may be set by first applying a high voltage (for example, 2.5 V) first potential 1060 across crossbar junction region 1030. State low “0” may be set by first applying a low voltage (for example, 1 V) first potential 1060 across crossbar junction region 1030. Reading of the two states can be accomplished by applying a reversed field (for example, −2 V) second potential 1061. When the magnitude of this “reading voltage” (second potential 1061) is smaller than that used for setting high “1” state (first potential 1060), current 1070 will start high and then reduce to the steady state at the reading voltage, second potential 1061 (see response state high 1410 on FIG. 14). When the magnitude of the reading voltage (second potential 1061) applied to crossbar junction region 1030 is higher than the magnitude of the applied writing voltage used for setting low “0” state (first potential 1060), the current 1070 will start low then increase to the steady state at the reading voltage, second potential 1061 (see response state low 1420 on FIG. 14).

It will be recognized by one of skill in the art that a sensor array may also be implemented using the crossbar devices and the methodology described above, where first potential 1060 represents an input to a crossbar device sensor element, and second potential 1061 is applied to “read” the state of the sensor element that results from the input.

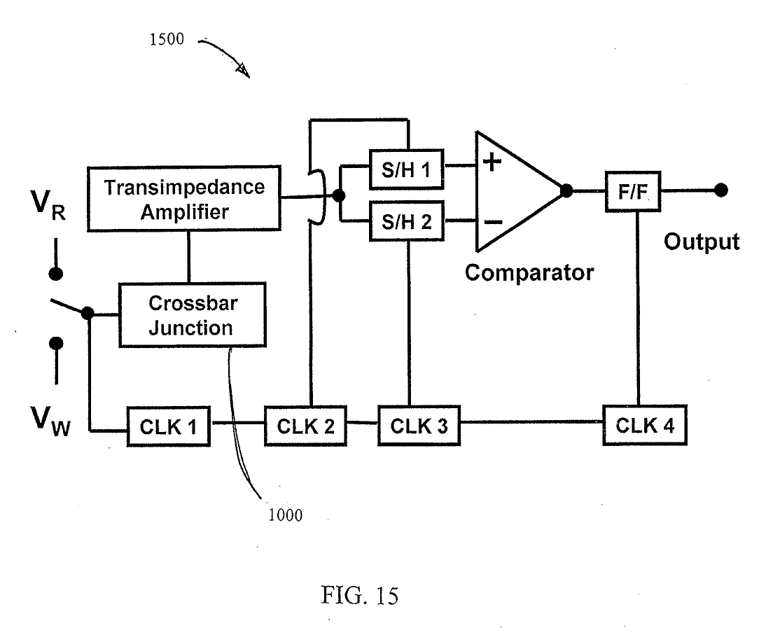

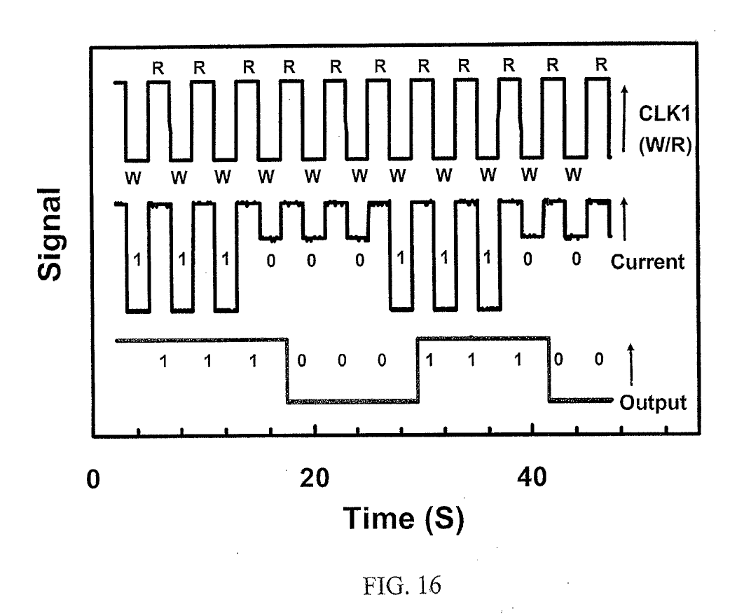

Referring to FIG. 15 and FIG. 10, an electronic memory circuit 1500 was constructed to capture the two opposite transient current states that represent two digitized states “0” and “1” written (W) by first applying first potential 1060 on crossbar junction region 1030 and then read (R) by applying reversed second potential 1061. In memory circuit 1500, the stored state is extracted from a self referenced signal, and the read function also acts to erase the previous state of the device. FIG. 16 depicts the waveforms captured with the read-write clock (CLK), current 1070 passing through crossbar junction region 1030, and the output of the memory circuit 1500 corresponding to the writing and reading back the bit sequence 11100011100. The circuit is analogous to conventional dynamic random access memory (DRAM) circuits where a reference capacitive line is charged and then differentially compared using an amplifier to a second capacitive line that is either pulled up or pulled down by the charge from a memory cell.

Embodiments of the present disclosure may also find application in reconfigurable electronic devices of a more general purpose nature. For example tuning the characteristics of transistors for analog electronic applications where device characteristics must be matched in order to achieve certain levels of performance.

All of the compositions and methods disclosed and claimed herein can be made and executed without undue experimentation in light of the present disclosure. While the compositions and methods of this invention have been described in terms of preferred embodiments, it will be apparent to those of skill in the art that variations may be applied to the compositions and methods and in the steps or in the sequence of steps of the method described herein without departing from the concept, spirit and scope of the invention. More specifically, it will be apparent that certain agents which are both chemically and physiologically related may be substituted for the agents described herein while the same or similar results would be achieved. All such similar substitutes and modifications apparent to those skilled in the art are deemed to be within the spirit, scope and concept of the invention as defined by the appended claims.

The appended claims are not to be interpreted as including means-plus-function limitations, unless such a limitation is explicitly recited in a given claim using the phrase(s) “means for” and/or “step for,” respectively.

### REFERENCES

The following references, to the extent that they provide exemplary procedural or other details supplementary to those set forth herein, are specifically incorporated herein by reference.
Gustafsson et al., Nature, 357:477-479, 1992.
Jager et al., Science, 288:2335-2338, 2000.
Eckhardt et al., . J. Phys. Chem. 91:1303-1315, 1989.
Cheng & Lonergan, J. Am. Chem. Soc. 126:10536-10537, 2004.
Chiang et al., Phys. Rev. Lett. 39:1098-1101, 1977.
Angelopoulos, IBM J. Res. & Dev. 45:57-75, 2001.
Faied et al., Macromolecules, 28:284-287, 1995.
MacInnes et al., J. Chem. Soc. Chem. Comm. 317-319, 1981.
Bredas & Street, Acc. Chem. Res. 18:309-315, 1985.
Burroughes et al., Nature, 335:137-141, 1988.
Cheng et al., J. Am. Chem. Soc. 126:8666-8667, 2004.
Burroughes et al., Nature 347, 539-541, 1990.
Gurunathan et al., Mat. Chem. Phys. 61:173-191, 1999.
Patil. et al., J. Am. Chem. Soc. 109:1858-1859, 1987.
Bidan et al., J. Phys. D: Appl. Phys. 21:1043-1054, 1988.
Blom et al., Phys. Rev. B. 55:R656-R659, 1997.
Pai, J. Chem. Phys. 52:2285-2291, 1970.
deMello et al. Phys. Rev. B, 57:12951-12963, 1998.
Lu & Chao, IEEE J. Solid-State Circuits, SC-19: 451-454, 1984.
Green et al., Nature, 445:414-417, 2007.
Cerofolini & Mascolo, Semicond. Sci. Technol. 21:1315-1325, 2006.
Smela, J. Micromech. Microeng. 9:1-18, 1999.

1. A method for generating a current comprising:
applying a first potential across an organic polymer that is doped with at least a first polyelectrolyte; and
applying a second potential across the organic polymer to generate the current;
where the current is dependent on the first potential that was applied across the organic polymer.

2. The method of claim 1, wherein the organic polymer comprises polyacetylene (PA), polythiophene (PT), polyaniline, polyphenylene (PPP), poly(phenylene vinylene) or a derivative thereof.

3. The method of claim 1, wherein the organic polymer comprises polypyrrole (PPy) or a derivative thereof.

4. The method of claim 1, wherein the polyelectrolyte comprises an anion having a molecule weight (MW) of between about 100 and about 1,000,000.

5. The method of claim 1, wherein the polyelectrolyte comprises a surfactant.

6. The method of claim 1, wherein the polyelectrolyte comprises a monovalent anion.

7. The method of claim 1, wherein the polyelectrolyte comprises a polyacrylamidoglycolic acid (PAGA), poly(diallyldimethylammonium chloride) (PDMA), poly(sodium styrenesulfonate) (PSS), polystyrene sulfonate (SPS), poly(acrylic acid) (PAA), poly(vinyl phosphate) (PVP), poly(2-acrylamido-2-methyl-1-propanesulfonicacid) (PAMPS), poly(2-acrylamidoglycolic acid), poly(2-hydroxy-4-N-methacrylamidobenzoic acid) (PHMA), poly(sodium thiophene-3-carboxylate) (PSTC), poly(sodium phenylenecarboxylate) (PSPC), sulfonated poly(benzobisthiazole) (PBT), sulfated poly((3-hydroxyether), sulfated poly(butadiene), sulfated poly(imide), sulfated poly(methacrylate), bis(2-ethylhexyl)sulfosuccinate, dodecylbenzenesulfonic acid (DBSA), dodecylsulfate, tetradecyltrimethylammonium bromide (TTAB), tetraethylammonium p-toluensulfonate, toluenesulfonate, pyrenesulfonate, pyrene-1,3,6,8-tetrasulfonate, dodecylbenzenesulfonate, 1,2-bis(decyloxycarbonyl)ethanesulfonate, octachloro-dirhenate (Re₂Cl₈), or tetraphenylborate anion.

8. The method of claim 1, wherein the polyelectrolyte comprises a dodecylbenzenesulfonate⁻ (DBS) anion.

9. The method of claim 8, wherein the polyelectrolyte comprises sodium dodecylbenzenesulfonate⁻ (DBS).

10. The method of claim 1, wherein the first polyelectrolyte comprises a polyelectrolyte anion being concentrated in the organic polymer at a ratio (of the organic polymer to the polyelectrolyte anion) of between about 6:1 and about 4:1.

11. The method of claim 10, wherein the polyelectrolyte comprises a polyelectrolyte anion being concentrated in the organic polymer in a concentration of about 1×10²¹ molecules per cm³.

12. The method of claim of claim 1, wherein the organic polymer is also doped with a second polyelectrolyte.

13. The method of claim 12, wherein the second polyelectrolyte comprises an alkali metal cation.

14. The method of claim 13, wherein the alkali metal cation comprises lithium.

15. The method of claim 12, wherein the second polyelectrolyte comprises lithium perchlorate.

16. The method of claim 1, wherein the second potential is a reverse potential as compared to the first potential.

17. The method of claim 1, wherein the organic polymer is between about 1 nm and about 100 μm in length.

18. The method of claim 1, wherein the organic polymer is between about 0.1 and about 100 μm in length.

19. The method of claim 1, wherein the organic polymer is between about 1 and about 20 μm in length.

20. The method of claim 1, wherein the magnitude of the first potential and the magnitudes of the second potential are different.

21. The method of claim 20, wherein the difference in the magnitude of the first potential and the magnitude of the second potential is between about 3.0 and 4.5 V.

22. The method of claim 20, wherein the magnitude of the second potential is greater than the magnitude of the first potential.

23. The method of claim 20, wherein the magnitude of the first potential is greater than the magnitude of the second potential.

24. The method of claim 1, further comprising determining whether the current resulting from the second potential increases or decreases over time.

25. A circuit comprising an organic polymer doped with at least a first polyelectrolyte, wherein the organic polymer is in electronic communication with at least a first conductor and a second conductor.

26. The circuit of claim 25, wherein the organic polymer comprises polyacetylene (PA), polythiophene (PT), polyaniline, polyphenylene (PPP), poly(phenylene vinylene) or a derivative thereof.

27. The circuit of claim 25, wherein the organic polymer comprises polypyrrole (PPy) or a derivative thereof.

28. The circuit of claim 25, wherein the polyelectrolyte comprises an anion having a molecule weight (MW) of between about 100 and about 1,000,000.

29. The circuit of claim 25, wherein the polyelectrolyte comprises a surfactant.

30. The circuit of claim 25, wherein the polyelectrolyte comprises a monovalent anion.

31. The circuit of claim 25, wherein the polyelectrolyte comprises a polyacrylamidoglycolic acid (PAGA), poly(diallyldimethylammonium chloride) (PDMA), poly(sodium styrenesulfonate) (PSS), polystyrene sulfonate (SPS), poly(acrylic acid) (PAA), poly(vinyl phosphate) (PVP), poly(2-acrylamido-2-methyl-1-propanesulfonicacid) (PAMPS), poly(2-acrylamidoglycolic acid), poly(2-hydroxy-4-N-methacrylamidobenzoic acid) (PHMA), poly(sodium thiophene-3-carboxylate) (PSTC), poly(sodium phenylenecarboxylate) (PSPC), sulfonated poly(benzobisthiazole) (PBT), sulfated poly((3-hydroxyether), sulfated poly(butadiene), sulfated poly(imide), sulfated poly(methacrylate), bis(2-ethylhexyl)sulfosuccinate, dodecylbenzenesulfonic acid (DBSA), dodecylsulfate, tetradecyltrimethylammonium bromide (TTAB), tetraethylammonium p-toluensulfonate, toluenesulfonate, pyrenesulfonate, pyrene-1,3,6,8-tetrasulfonate, dodecylbenzenesulfonate, 1,2-bis(decyloxycarbonypethanesulfonate, octachloro-dirhenate (Re₂Cl₈), or tetraphenylborate anion.

32. The circuit of claim 25, wherein the polyelectrolyte comprises a dodecylbenzenesulfonate⁻ (DBS) anion.

33. The circuit of claim 32, wherein the polyelectrolyte comprises sodium dodecylbenzenesulfonate⁻ (DBS).

34. The circuit of claim 25, wherein the first polyelectrolyte comprises a polyelectrolyte anion being concentrated in the organic polymer at a ratio (of the organic polymer to the polyelectrolyte anion) of between about 6:1 and about 4:1.

35. The circuit of claim 34, wherein the polyelectrolyte comprises a polyelectrolyte anion being concentrated in the organic polymer in a concentration of about 1×10²¹ molecules per cm³.

36. The circuit of claim 25, wherein the organic polymer is also doped with a second polyelectrolyte.

37. The circuit of claim 36, wherein the second polyelectrolyte comprises an alkali metal cation.

38. The circuit of claim 36, wherein the alkali metal cation comprises lithium.

39. The circuit of claim 37, wherein the second polyelectrolyte comprises lithium perchlorate.

40. The circuit of claim 25, where the circuit is a memory circuit.

41. The circuit of claim 25, wherein the first conductor or the second conductor is an injecting electrode.

42. The circuit of claim 25, wherein the first conductor or the second conductor comprises Au, Pt, Cu or Ag.

43. The circuit of claim 25, wherein:
the first conductor comprises a first conductor material;
the second conductor comprises a second conductor material; and
the first conductor material and the second conductor material are not the same.

44. The circuit of claim 25, wherein the distance between the first and second conductor is between about 1 nm and about 100 μm.

45. The circuit of claim 25, wherein the distance between the first and second conductor is between about 0.1 and about 100 μm.

46. The circuit of claim 25, wherein the distance between the first and second conductor is between about 1 and about 20 μm.

47. An array comprising two or more circuits according to claim 25.

48. The array of claim 47, the array being a sensor array.

49. An apparatus comprising a computer, said computer comprising a circuit according to claim 25.

50. A crossbar device comprising:
a first conductor adjacent to a crossbar junction region, the first conductor having a width of about 100 μm or less;
a second conductor adjacent to the crossbar junction region, the second conductor being separated from the first conductor at the crossbar junction region by a separation distance, the second conductor having a width of about 100 μm or less, and the separation distance being about 1 μm or less; and
an organic polymer within the crossbar junction region, where the organic polymer is doped with at least a first polyelectrolyte, and the organic polymer is in electronic communication with the first conductor and the second conductor;
where the crossbar device is configured such that:
a first potential can be applied across the organic polymer using the first conductor and the second conductor;
a second potential can be applied across the organic polymer using the first conductor and the second conductor to generate a current that passes through the first conductor, the organic polymer, and the second conductor; and
the current is dependent on the first potential.

51. The crossbar device of claim 50, wherein the organic polymer comprises polyacetylene (PA), polythiophene (PT), polyaniline, polyphenylene (PPP), poly(phenylene vinylene) or a derivative thereof.

52. The crossbar device of claim 50, wherein the organic polymer comprises polypyrrole (PPy) or a derivative thereof.

53. The crossbar device of claim 50, wherein the polyelectrolyte comprises an anion having a molecule weight (MW) of between about 100 and about 1,000,000.

54. The crossbar device of claim 50, wherein the polyelectrolyte comprises a surfactant.

55. The crossbar device of claim 50, wherein the polyelectrolyte comprises a monovalent anion.

56. The crossbar device of claim 50, wherein the polyelectrolyte comprises a polyacrylamidoglycolic acid (PAGA), poly(diallyldimethylammonium chloride) (PDMA), poly(sodium styrenesulfonate) (PSS), polystyrene sulfonate (SPS), poly(acrylic acid) (PAA), poly(vinyl phosphate) (PVP), poly(2-acrylamido-2-methyl-1-propanesulfonicacid) (PAMPS), poly(2-acrylamidoglycolic acid), poly(2-hydroxy-4-N-methacrylamidobenzoic acid) (PHMA), poly(sodium thiophene-3-carboxylate) (PSTC), poly(sodium phenylenecarboxylate) (PSPC), sulfonated poly(benzobisthiazole) (PBT), sulfated poly(β-hydroxyether), sulfated poly(butadiene), sulfated poly(imide), sulfated poly(methacrylate), bis(2-ethylhexyl)sulfosuccinate, dodecylbenzenesulfonic acid (DBSA), dodecylsulfate, tetradecyltrimethylammonium bromide (TTAB), tetraethylammonium p-toluensulfonate, toluenesulfonate, pyrenesulfonate, pyrene-1,3,6,8-tetrasulfonate, dodecylbenzenesulfonate, 1,2-bis(decyloxycarbonypethanesulfonate, octachloro-dirhenate (Re₂Cl₈), or tetraphenylborate anion.

57. The crossbar device of claim 50, wherein the polyelectrolyte comprises a dodecylbenzenesulfonate⁻ (DBS) anion.

58. The crossbar device of claim 57, wherein the polyelectrolyte comprises sodium dodecylbenzenesulfonate⁻ (DBS).

59. The crossbar device of claim 50, wherein the first polyelectrolyte comprises a polyelectrolyte anion being concentrated in the organic polymer at a ratio (of the organic polymer to the polyelectrolyte anion) of between about 6:1 and about 4:1.

60. The crossbar device of claim 59, wherein the polyelectrolyte comprises a polyelectrolyte anion being concentrated in the organic polymer in a concentration of about 1×10²¹ molecules per cm³.

61. The crossbar device of claim 50, wherein the organic polymer is also doped with a second polyelectrolyte.

62. The crossbar device of claim 61, wherein the second polyelectrolyte comprises an alkali metal cation.

63. The crossbar device of claim 61, wherein the alkali metal cation comprises lithium.

64. The crossbar device of claim 62, wherein the second polyelectrolyte comprises lithium perchlorate.

65. The crossbar device of claim 50, wherein the crossbar device is a memory device.

66. The crossbar device of claim 50, wherein the first conductor or the second conductor is an injecting electrode.

67. The crossbar device of claim 50, wherein the first conductor or the second conductor comprises Au, Pt, Cu or Ag.

68. The crossbar device of claim 50, wherein the first conductor or the second conductor comprises a metal oxide.

69. The crossbar device of claim 68, wherein the metal oxide is tungsten oxide.

70. The crossbar device of claim 50, wherein:
the first conductor comprises a first conductor material;
the second conductor comprises a second conductor material; and
the first conductor material and the second conductor material are not the same.

71. The crossbar device of claim 50, where the separation distance is between about 1 nm and about 500 nm.

72. The crossbar device of claim 71, where the separation distance is about 200 nm.

73. The crossbar device of claim 50, where the width of the first conductor and the width of the second conductor are each about 20 μm or less.

74. The crossbar device of claim 50, where it can be determined whether the current resulting from the second potential increases or decreases over time.

75. An array comprising two or more crossbar devices according to claim 50.

76. The array of claim 75, the array being a sensor array.

77. An apparatus comprising a computer, said computer comprising a crossbar device according to claim 50.
